(19) United States
(12) Patent Application Publication
(10) Pub. No.: US 2010/0147088 A1
(43) Pub. Date: Jun. 17, 2010

(54) ELECTRONIC DEVICE TEST APPARATUS AND METHOD OF TESTING ELECTRONIC DEVICES

(75) Inventors: Akihiko Ito, Tokyo (JP); Koya Karino, Tokyo (JP); Yoshihito Kobayashi, Tokyo (JP)

Correspondence Address: GREENBLUM & BERNSTEIN, P.L.C., 1950 ROLAND CLARKE PLACE, RESTON, VA, 20191, US

(73) Assignee: ADVANTEST CORPORATION, Tokyo (JP)

(21) Appl. No.: 12/161,067

(22) PCT Filed: Jan. 17, 2006
(86) PCT No.: PCT/JP2006/300557

§ 371 Date: Jul. 16, 2008

(51) Int. Cl. G01N 1/00; G01R 31/02

(52) U.S. Cl. 73/864.81; 324/537

(57) ABSTRACT

An electronic device test apparatus used for bringing the ICs into electrical contact with contact parts of the test head in the state where the ICs are held on a test tray and running tests on the electrical characteristics of ICs, the electronic device test apparatus including an inversion system for rotating the test tray which holds a plurality of ICs in a direction dropping ICs which are insufficiently held at least once before testing.

### TECHNICAL FIELD

The present invention relates to an electronic device test apparatus for testing semiconductor integrated circuit chips or other electronic devices (hereinafter referred to representatively as “IC devices”).

### BACKGROUND ART

In the process of production of IC devices and other electronic devices, an electronic device test apparatus is used for testing IC devices for performance or functions in a packaged state.

A handler, forming part of an electronic device test apparatus, reloads a large number of IC devices from a customer tray to a test tray, conveys the test tray inside the handler, brings the IC devices into electrical contact with the contact parts of a test head in the state held on the test tray, and the main body of the electronic device test apparatus (hereinafter also referred to as a “tester”) executes a test. Further, after the test ends, the test tray holding the IC devices is carried out from the test head and the devices are reloaded on customer trays in accordance with the test results so as to sort them into categories of good devices and defective devices.

In a handler of the type circulating a test tray, when reloading ICs from a customer tray to the test tray, for example as shown in FIG. 23, sometimes the ICs will be placed on the test tray TST at a slant and the ICs will not be suitably held in the carriers 65 of the test tray TST. If a test tray with ICs unsuitably held is conveyed to the test head to be tested, when pushing the ICs against the contact parts of the test head, the test tray, contact parts, pushers for pushing the ICs, or ICs themselves are liable to be damaged.

To prevent such a situation, for example, it may be considered to use image processing, sensors, etc. to measure the slant of the ICs with respect to the test tray so as to detect any ICs unsuitably held in the test tray. However, since the test tray holds a large number of (for example 64 or 128) ICs, detecting each and every one of these causes increased costs and lower throughput.

Further, even if using image processing, sensors, etc. to detect ICs unsuitably held in a test tray, a mechanism for correctly repositioning the ICs in the carriers of the test tray is necessary. This also causes increased costs and lower throughput.

### DISCLOSURE OF THE INVENTION

The present invention has as its object the provision of an electronic device test apparatus easily removing ICs unsuitably held on a test tray and able to prevent damage to a test tray and ICs.

(1) To achieve the above object, according to the present invention, there is provided an electronic device test apparatus used for bringing the devices under test into electrical contact with contact parts of the test head in the state where the devices under test are held on a test tray, and running tests on the electrical characteristics of the devices under test, the electronic device test apparatus comprising: a posture changing means for changing a posture of the test tray which holds the devices under test in a direction dropping devices under test which are insufficiently held at least once before testing (see claim 1).

In the present invention, a posture of the test tray is changed in a direction dropping devices under test at least once before testing the devices under test. Due to this, it is possible to drop the ICs unsuitably held on the test tray and easily remove the electronic devices before testing, so it is possible to prevent damage to the test tray and the devices under test.

While not particularly limited in the above invention, preferably the posture changing means changes the test tray from a horizontal posture to an inverted posture and furthermore changes it from the inverted posture to a predetermined posture (see claim 2).

While not particularly limited in the above invention, preferably the posture changing means changes the test tray from a horizontal posture to an inverted posture, maintains the inverted posture for a predetermined time, then changes it from the inverted posture to a predetermined posture (see claim 3).

While not particularly limited in the above invention, preferably the posture changing means changes the test tray from a horizontal posture to an inverted posture, vibrates the test tray in the inverted posture, then changes it from the inverted posture to a predetermined posture (see claim 4).

While not particularly limited in the above invention, preferably the apparatus further comprises: a collection means for collecting the device under test dropped from the test tray which is in an inverted posture by the posture changing means (see claim 5).

While not particularly limited in the above invention, preferably the apparatus further comprises: a returning means for returning the device under test collected by the collection means to the test tray, another test tray, or a customer tray (see claim 6).

While not particularly limited in the above invention, preferably the apparatus further comprises an application unit for applying thermal stress of a predetermined temperature to the devices under test in the state where the devices under test are held on a test tray; and a test unit for pushing the devices under test held on the test tray which is in a predetermined posture against the test head so as to bring the devices under test held on the test tray into contact with the contact parts, and the predetermined posture is a vertical posture.

While not particularly limited in the above invention, preferably the posture changing means is provided inside the application unit.

While not particularly limited in the above invention, preferably the posture changing means is provided in an posterior half of the application unit.

While not particularly limited in the above invention, preferably the posture changing means is provided near an exit in the application unit.

While not particularly limited in the above invention, preferably the collection means is provided inside the application unit.

While not particularly limited in the above invention, preferably the returning means is provided inside the application unit and returns a device under test collected by the collection means to the test tray, another test tray, or a customer tray.

While not particularly limited in the above invention, preferably the apparatus further comprises: a loader unit for loading devices under test onto the test tray and carring the test tray in a horizontal posture to the application unit.

While not particularly limited in the above invention, preferably the apparatus further comprises: a loader unit for loading devices under test onto the test tray and carring the test tray in a horizontal posture to the application unit, and the posture changing means is provided between the loader unit and the application unit.

While not particularly limited in the above invention, preferably the apparatus comprises: a relieving unit for relieving thermal stress from the devices under test in the state where the devices under test are held on the test tray, and the relieving unit has a second posture changing means for changing the test tray from the predetermined posture to a horizontal posture inside the relieving unit.

While not particularly limited in the above invention, preferably the second posture changing means is provided at an anterior half part of the relieving unit.

While not particularly limited in the above invention, preferably the second posture changing means is provided near an inlet in the relieving unit.

While not particularly limited in the above invention, preferably the apparatus further comprises an unloader unit for receiving the test tray from the relieving unit and classifying the devices under test based on the test results.

While not particularly limited in the above invention, preferably the apparatus further comprises: an application unit for applying thermal stress of a predetermined temperature to the devices under test in the state where the devices under test are held on a test tray; and a test unit for pushing the devices under test held on the test tray which is in the predetermined posture against the test head so as to bring the devices under test held on the test tray into contact with the contact parts, and the predetermined posture is a horizontal posture.

While not particularly limited in the above invention, preferably the posture changing means changes the posture of the test tray before being carried into the application unit.

While not particularly limited in the above invention, preferably the apparatus further comprises: a loader unit for loading the devices under test onto the test tray and carring the test tray in a horizontal posture to the application unit, and the posture changing means is provided inside the loader unit.

While not particularly limited in the above invention, preferably the collection means is provided inside the loader unit.

While not particularly limited in the above invention, preferably the returning means is provided inside the loader unit and returns a device under test collected by the collection means to the test tray, another test tray, or customer tray.

While not particularly limited in the above invention, preferably the apparatus further comprises: a relieving unit for relieving thermal stress from the devices under test in the state where the devices under test are held on the test tray.

While not particularly limited in the above invention, preferably the apparatus further comprises an unloader unit for receiving the test tray from the relieving unit and classifying the devices under test based on the test results.

(2) To achieve the above object, according to the present invention, there is provided a method of testing electronic devices bringing the devices under test into electrical contact with contact parts of the test head in the state where the devices under test are held on a test tray, and running tests on the electrical characteristics of the devices under test, the method of testing electronic devices comprising: a posture changing step of changing a posture of the test tray which holds the devices under test in a direction dropping devices under test which are insufficiently held at least once before testing (see claim 7).

In the present invention, a posture of the test tray is changed in a direction dropping devices under test at least once before testing the devices under test. Due to this, it is possible to drop devices under test unsuitably held on a test tray and easily remove such electronic devices before testing, so it is possible to suppress breakage of the test tray and devices under test.

While not particularly limited in the above invention, preferably, in the posture changing step, the test tray is changed from a horizontal posture to an inverted posture and furthermore is changed from the inverted posture to the predetermined posture (see claim 8).

While not particularly limited in the above invention, preferably, in the posture changing step, the test tray is changed from a horizontal posture to an inverted posture, is maintained in the inverted posture for a predetermined time, then is changed from the inverted posture to the predetermined posture (see claim 9).

While not particularly limited in the above invention, preferably, in the posture changing step, the test tray is changed from a horizontal posture to an inverted posture, is vibrated in the inverted posture, then is changed from the inverted posture to the predetermined posture (see claim 10).

While not particularly limited in the above invention, preferably the method further comprises: a collection step of collecting a device under test dropped from the test tray which is in an inverted posture (see claim 11).

While not particularly limited in the above invention, preferably the method further comprises: a returning step of returning the device under test collected in the collection step to the test tray, another test tray, or a customer tray (see claim 12).

While not particularly limited in the above invention, preferably the method further comprises: an application step of applying thermal stress of a predetermined temperature to the devices under test in the state where the devices under test are held on a test tray; and a test step of pushing the devices under test held on the test tray in a predetermined posture against the test head so as to bring the devices under test held on the test tray into contact with the contact parts, and the predetermined posture is a vertical posture.

While not particularly limited in the above invention, preferably the posture changing step is included in the application step.

While not particularly limited in the above invention, preferably the test tray is changed from a horizontal posture to the predetermined posture in an posterior half part of the application step.

While not particularly limited in the above invention, preferably the collection step is included in the application step.

While not particularly limited in the above invention, preferably the returning step is included in the application step and a device under test collected in the collection step is returned to the test tray, another test tray, or a customer tray.

While not particularly limited in the above invention, preferably the method further comprises: a loader step of loading the devices under test onto the test tray and transferring the test tray in a horizontal posture to the application step.

While not particularly limited in the above invention, preferably the method further comprises: a loader step of loading devices under test onto the test tray and transferring the test tray in a horizontal posture to the application step, and the posture changing step is executed between the loader step and the application step.

While not particularly limited in the above invention, preferably the method further comprises: a relieving step of relieving thermal stress from the devices under test in the state where the devices under test are held on the test tray, and the test tray is changed from the predetermined posture to a horizontal posture in the relieving step.

While not particularly limited in the above invention, preferably the test tray is changed from the predetermined posture to a horizontal posture in a anterior half part of the relieving step.

While not particularly limited in the above invention, preferably the method further comprises: an unloader step of receiving a test tray from the relieving step and classifying the devices under test based on the test results.

While not particularly limited in the above invention, preferably the method comprises: an application step of applying thermal stress of a predetermined temperature to the devices under test in the state where the devices under test are held on a test tray; and a test step of pushing the devices under test held on the test tray in the predetermined posture against the test head so as to bring the devices under test held on the test tray into contact with the contact parts, and the predetermined posture is a horizontal posture.

While not particularly limited in the above invention, preferably the posture changing step is executed before the application step.

While not particularly limited in the above invention, preferably the method further comprises: a loader step of loading the devices under test onto the test tray and transferring the test tray in a horizontal posture to the application step, and the posture changing step is included in the loader step.

While not particularly limited in the above invention, preferably the collection step is included in the loader step.

While not particularly limited in the above invention, preferably the returning step is included in the loader step and the devices under test collected in the collection step are returned to the test tray, another test tray, or customer tray.

While not particularly limited in the above invention, preferably the method further comprises: a relieving step of relieving thermal stress from the devices under test in the state where the devices under test are held on the test tray.

While not particularly limited in the above invention, preferably the method further comprises: an unloader step of receiving the test tray from the relieving step and classifying the devices under test based on the test results.

### BRIEF DESCRIPTION OF THE DRAWINGS

FIG. 1 is a perspective view of an entire electronic device test apparatus according to a first embodiment of the present invention.

FIG. 2 is a side view showing an electronic device test apparatus according to a first embodiment of the present invention.

FIG. 3 is a conceptual view showing the handling of a tray in an electronic device test apparatus according to a first embodiment of the present invention.

FIG. 4 is a schematic perspective view showing the 3D handling of a test tray in an electronic device test apparatus according to a first embodiment of the present invention.

FIG. 5 is a schematic perspective view showing the handling of the test tray along the vertical direction in a soak chamber of an electronic device test apparatus according to an embodiment of the present invention.

FIG. 6 is a schematic perspective view showing the handling of the test tray along the vertical direction in an unsoak chamber of an electronic device test apparatus according to an embodiment of the present invention.

FIG. 7 is a disassembled perspective view showing a test tray used in an electronic device test apparatus according to an embodiment of the present invention.

FIG. 8 is a perspective view showing a holder provided in a test tray shown in FIG. 7.

FIG. 9 is a schematic perspective view showing the entire mechanism for handling a test tray of an electronic device test apparatus according to an embodiment of the present invention.

FIG. 10 is a schematic cross-sectional view along the line x-x of FIG. 9.

FIG. 11 is a partial front view of the top of the inside of the soak chamber seen along the xi direction of FIG. 9.

FIG. 12 is a partial side view of the bottom of the inside of the soak chamber seen along the xii direction of FIG. 9.

FIG. 13 is a schematic view showing a collection system and a return system of an electronic device test apparatus according to a first embodiment of the present invention.

FIG. 14 is a cross-sectional view for explaining a connection state of ICs held on a test tray and contact pins of a test head in a first embodiment of the present invention.

FIG. 15 is a schematic perspective view showing the handling of the test tray along the vertical direction in a soak chamber of an electronic device test apparatus according to another embodiment of the present invention.

FIG. 16 is a schematic perspective view showing the handling of the test tray along the vertical direction in a soak chamber of an electronic device test apparatus according to still another embodiment of the present invention.

FIG. 17 is a perspective view showing an entire electronic device test apparatus according to a second embodiment of the present invention.

FIG. 18 is a schematic cross-sectional view along the line XVIII-XVIII of FIG. 17.

FIG. 19 is a conceptual view showing the handling of a tray in an electronic device test apparatus according to a second embodiment of the present invention.

FIG. 20 is a schematic perspective view showing the 3D handling of a test tray in an electronic device test apparatus according to a second embodiment of the present invention.

FIG. 21 is a front view showing an inversion system and a collection system of an electronic device test apparatus according to a second embodiment of the present invention.

FIG. 22 is a side view showing an inversion system and a collection system of an electronic device test apparatus according to a second embodiment of the present invention.

FIG. 23 is a schematic cross-sectional view showing an IC unsuitably held in a test tray.

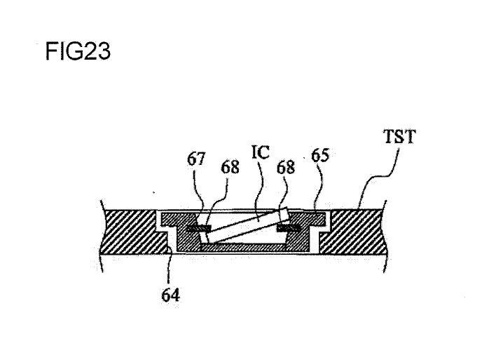

### DESCRIPTION OF NOTATIONS

1 . . . handler

100 . . . chamber unit

110 . . . soak chamber

111 . . . horizontal conveyance system

112 . . . vertical conveyance system

113 . . . inversion system

114 . . . exit

115 . . . collection system

116 . . . retrun system

120 . . . test chamber

130 . . . unsoak chamber

200 . . . storage unit

300 . . . loader unit

400 . . . unloader unit

5 . . . test head

TST . . . test tray

### BEST MODE FOR CARRYING OUT THE INVENTION

Below, embodiments of the present invention will be explained based on the drawings.

### First Embodiment

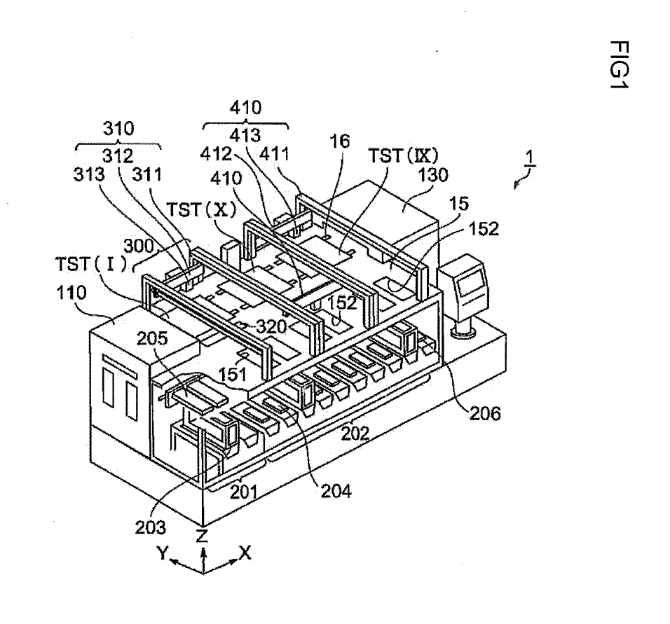

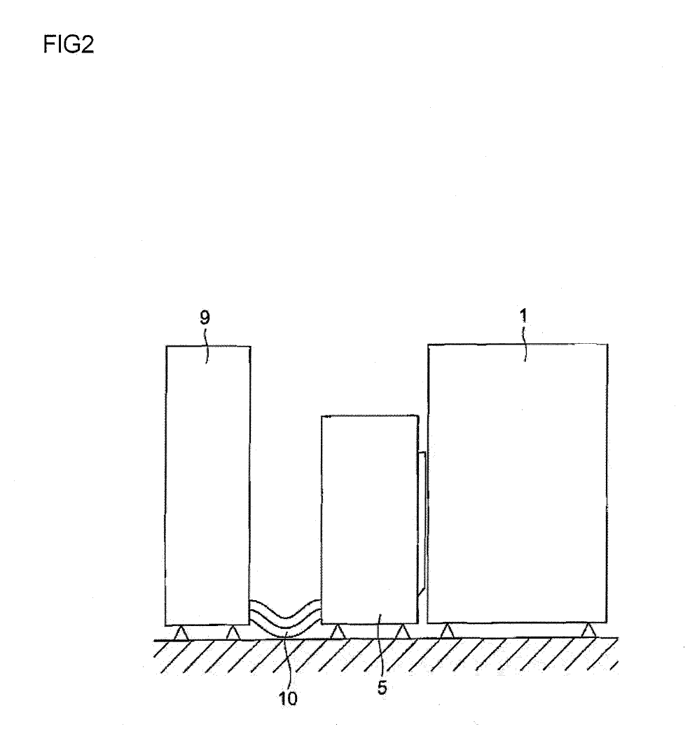

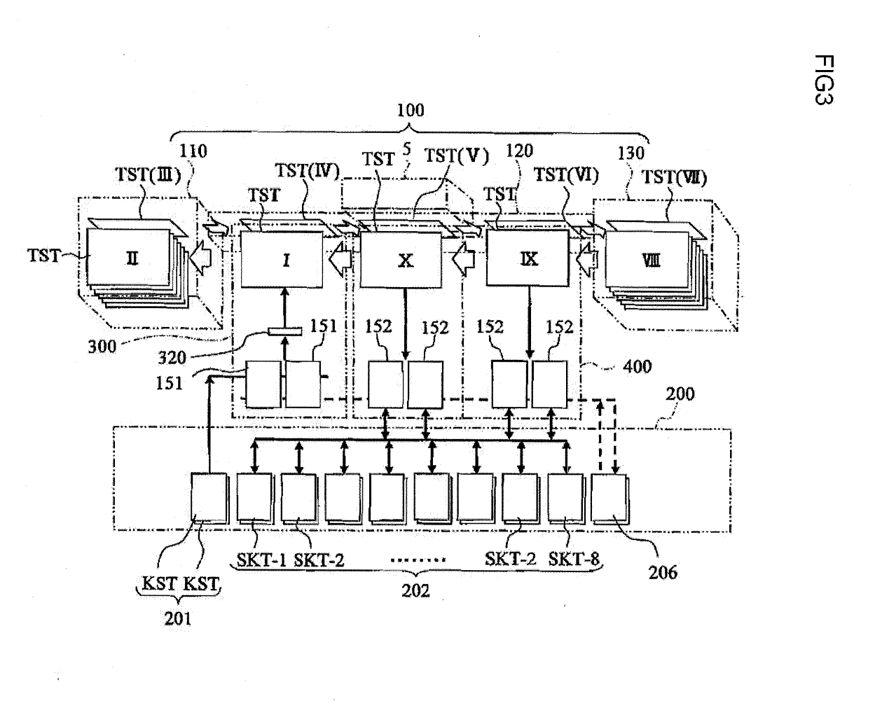

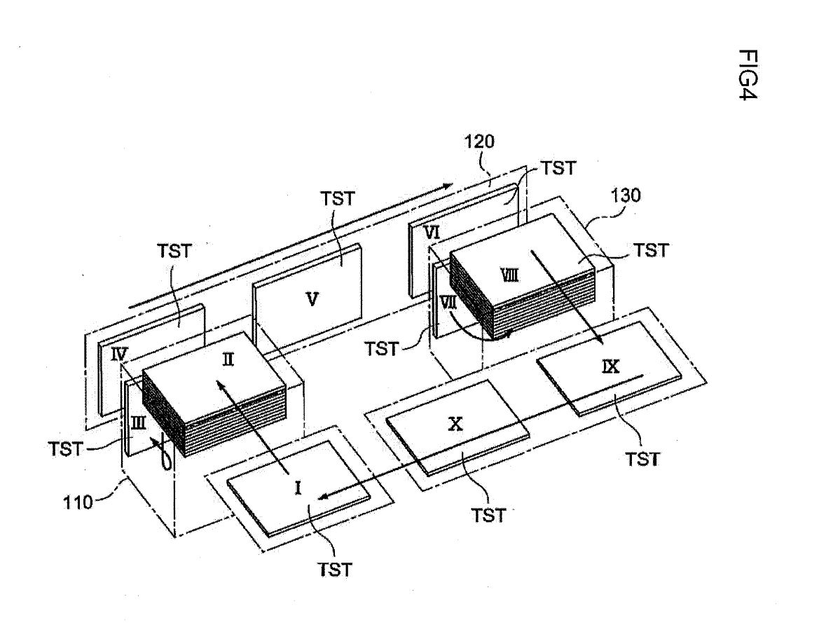

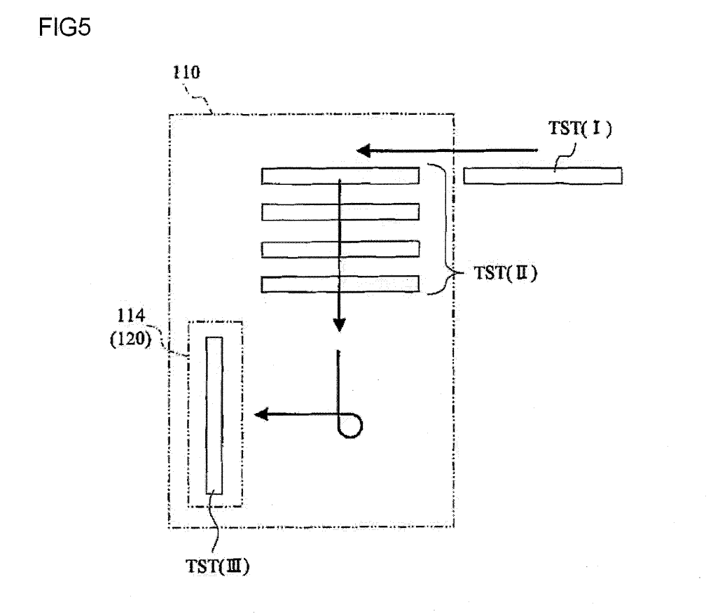

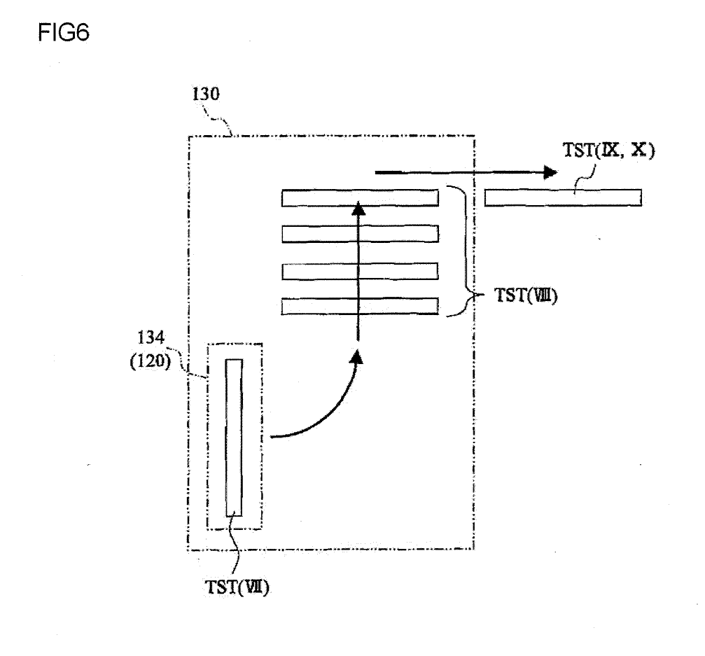

FIG. 1 is a perspective view of an entire electronic device test apparatus according to the present embodiment, FIG. 2 is a side view showing an electronic device test apparatus according to the present embodiment, FIG. 3 is a conceptual view showing the handling of a tray in an electronic device test apparatus according to the present embodiment, FIG. 4 is a schematic perspective view showing the 3D handling of a test tray in an electronic device test apparatus according to the present embodiment, FIG. 5 is a schematic perspective view showing the handling of the test tray along the vertical direction in a soak chamber of an electronic device test apparatus according to the present embodiment, FIG. 6 is a schematic perspective view showing the handling of the test tray along the vertical direction in an unsoak chamber of an electronic device test apparatus according to the present embodiment.

The electronic device test apparatus according to the present embodiment , as shown in FIG. 1 and FIG. 2, comprises: a handler 1 for handling an IC under test; a test head 5 with which ICs are electrically brought into contact; and a tester 9 sending test signals to this test head 5 and executing tests on the ICs.

The handler 1 in the present embodiment comprises: a chamber unit 100; a storage unit 200 for storing the pre-test ICs or classifying and storing post-test ICs; a loader unit 300 for sending pre-test ICs from the storage unit 200 to the chamber unit 100; and an unloader unit 400 for classifying and carrying out post-test IC devices tested in the chamber unit 100 to the storage unit 200.

This handler 1 is an apparatus for applying high temperature or low temperature thermal stress to the ICs at the time of a test, pushing the ICs against the test head 5, and, furthermore, classifying the ICs in accordance with the test results. A test in the state giving thermal stress is executed after reloading ICs from a tray on which a large number of ICs under test are held (hereinafter referred to as a “customer tray KST”) to a tray conveyed circulated inside the handler 1 (hereinafter referred to as a “test tray TST”).

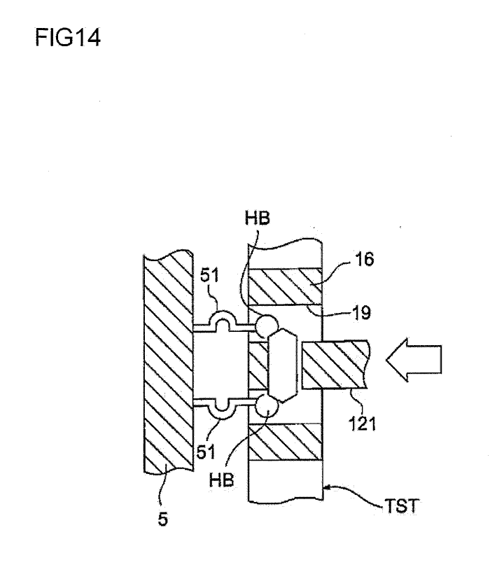

This test tray TST, as shown in FIG. 3 to FIG. 6, is loaded with ICs in the loader unit 300, then sent in a horizontal posture to the chamber unit 100 (position I in FIG. 3 and FIG. 4) , and converted from a horizontal posture to a vertical posture in the soak chamber 110 (position II→position III in FIG. 3 to FIG. 5). Further, in the test chamber 12, the ICs which are held on the test tray TST are pushed against the contact pins 51 of the test head 5 (see FIG. 14) and they are contacted so as to test on the electrical characteristics of the ICs (position IV→position V→position VI in FIG. 3 and FIG. 4). The ICs finished being tested are returned from the vertical posture to the horizontal posture in the unsoak chamber 130, then carried out to the unloader unit 400 (position VII→position VIII in FIG. 3, FIG. 4 and FIG. 6) and reloaded to customer trays KST in the unloader unit 400 in accordance with the test results (position IX and position X in FIG. 3, FIG. 4 and FIG. 6).

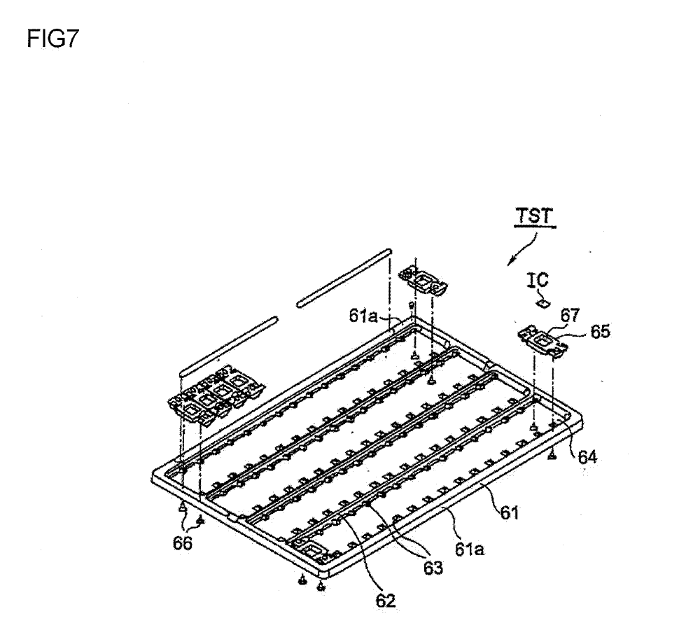

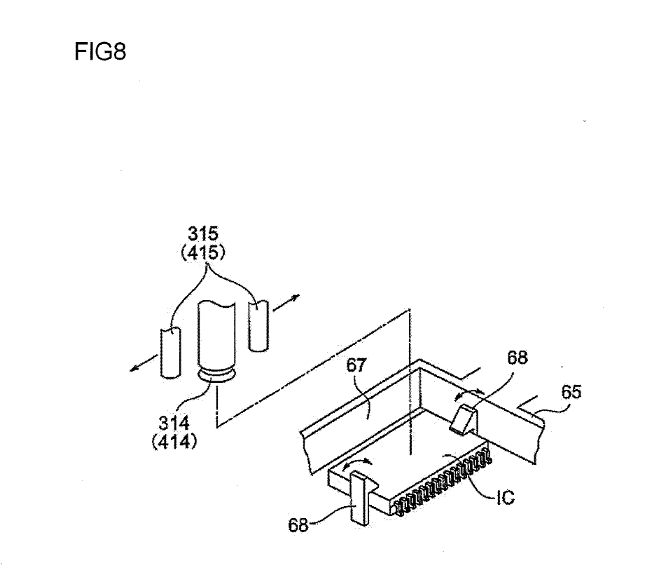

First, the structure of the test tray TST will be explained based on FIG. 7 and FIG. 8. FIG. 7 is a disassembled perspective view showing a test tray used in an electronic device test apparatus according to the present embodiment, while FIG. 8 is a perspective view showing a holder provided in a test tray shown in FIG. 7.

The test tray TST, as shown in FIG. 7, has a rectangular frame 61 provided with beams 62 in parallel at equal intervals. Pluralities of mounting pieces 63 are formed sticking out at the both sides of these beams 62 or at the side 61a of the frame 61 facing the beams 62 at equal intervals. Further, holders 64 are defined with reference to mounting pieces 63 between the facing beams 62 or between the facing beam 62 and the side 61a.

Each holder 64 holds one carrier 65. Each carrier 65 is attached to two mounting pieces 63 in a floating state by fasteners 66. In this example, 16×4 carriers 65 are attached to a single test tray TST.

The carriers 65 have the same shapes and same dimensions. A holder 67 for holding an IC is formed in each carrier 65. The holder 67 is designed in accordance with the shape of the IC to be held. In this example, it is a rectangular recess.

Each carrier 65, as shown in FIG. 8, is provided with hook shaped latches 68. The latches 68 are formed to stick out upward from the bottom surface of the holder 67. They are designed to be able to elastically deform due to the plastic material forming the carrier 65. By engaging the barb of the latches 68 with the surface of the IC held in the holder 67, positional deviation or springout of the IC can be prevented.

Latch release mechanisms 315, 415 are provided at the both side of the suction pads 314, 414 for picking up the ICs by suction.

When holding an IC in a holder 67, the latch release mechanism 315 spreads apart the two latches 68. At that time, the suction pad 314 releases the suction on the IC. Due to this, the IC can be held in the holder 67. The latch release mechanism 315 is then separated from the latches 68, whereby the latches 68 return to their original states by their elastic forces. Therefore, the IC engaged by the latches 68 will not drop off from the test tray TST even if the test tray TST becomes a vertical posture. Note that the suction pad 314 and the latch release mechanism 315 in this case are provided at the later mentioned XY conveyance system 310 of the loader unit 300.

When taking out an IC from a holder 67, the latch release mechanism 415 spreads apart the two latches 68. At that time, the suction pad 414 picks up the IC by suction. Due to this, the IC can be taken out from the holder 67. When the latch release mechanism 415 moves away from the latches 68, the latches 68 return to their original states by elastic force. Note that the suction pad 414 and the latch release mechanism 415 in this case are provided at the later mentioned XY conveyance system 410 of the unloader unit 400.

Next, FIG. 1 to FIG. 6 and FIG. 9 to FIG. 14 will be referred to so as to explain the structures of the different parts of the handler 1.

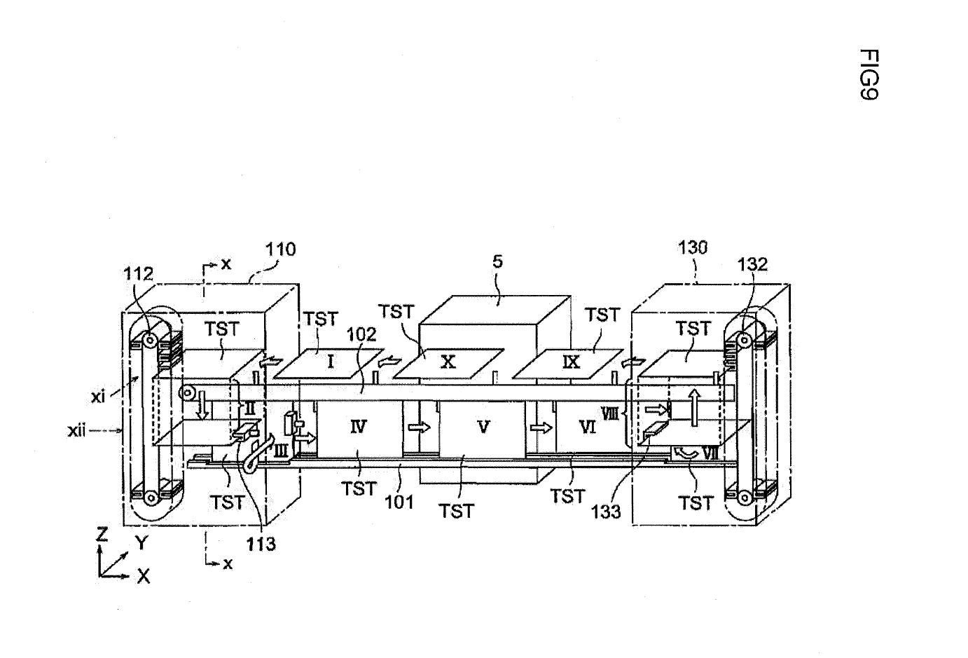

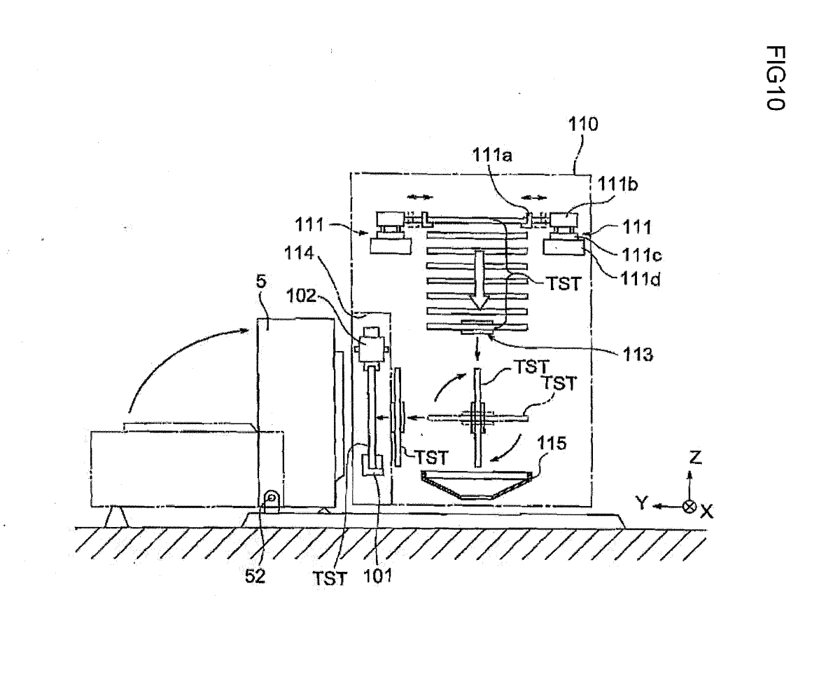

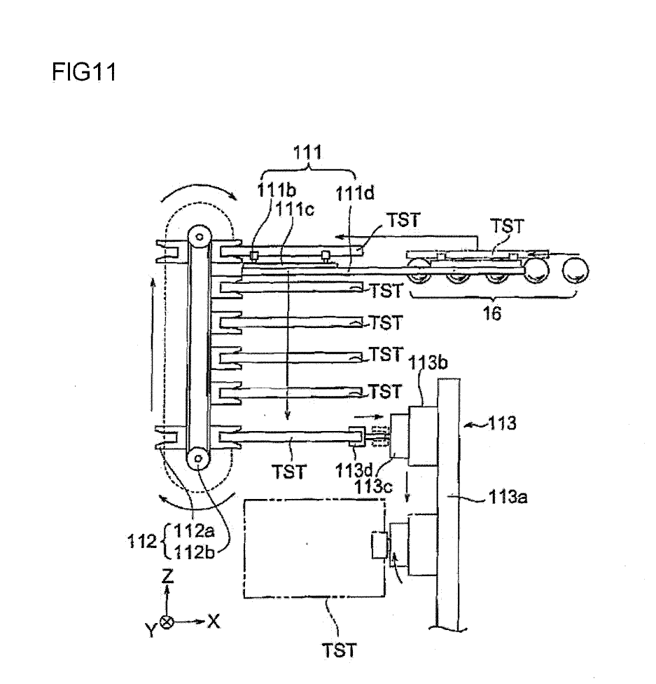

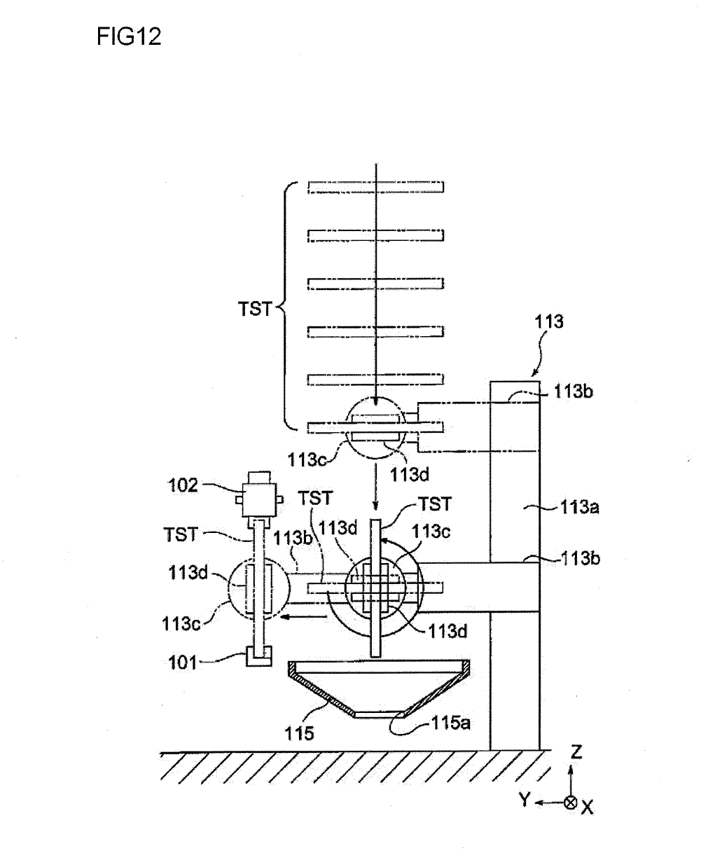

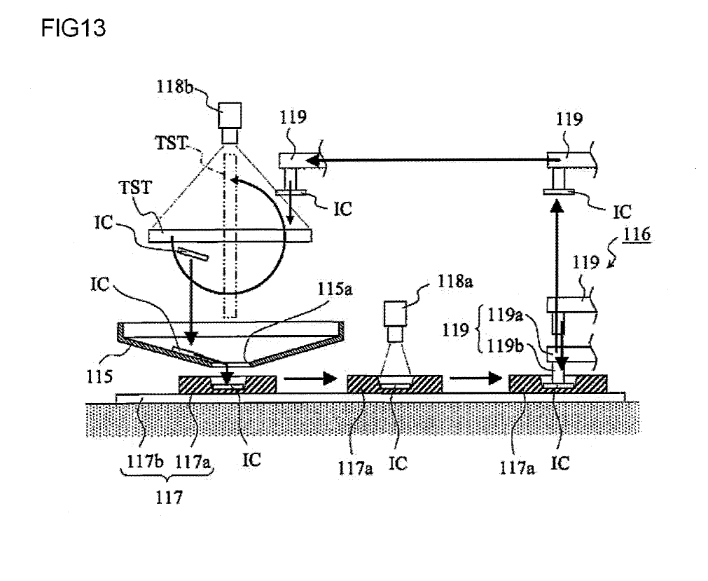

FIG. 9 is a schematic perspective view showing the entire mechanism for handling a test tray of an electronic device test apparatus according to the present embodiment, FIG. 10 is a schematic cross-sectional view along the line x-x of FIG. 9, FIG. 11 is a partial front view of the top of the inside of the soak chamber seen along the xi direction of FIG. 9, FIG. 12 is a partial side view of the bottom of the inside of the soak chamber seen along the xii direction of FIG. 9, FIG. 13 is a schematic view showing a collection system and a return system of an electronic device test apparatus according to the present embodiment, and FIG. 14 is a cross-sectional view for explaining a connection state of ICs held on a test tray and contact pins of a test head in the present embodiment.

The storage unit 200 comprises: a pre-test IC stocker 201 for storing pre-test ICs; a post-test IC stocker 202 for storing ICs classified in accordance with the test results; and a tray conveyance system 205 having an operating range encompassing all stockers.

Each of these IC stocker 201 and post-test IC stocker 202 comprises: a frame-shaped tray support frame 203; and an elevator 204 for entering from the bottom of the tray support frame 203 and rising upward. A plurality of customer trays KST are stacked in each tray support frame 203. Only these stacked customer trays KST are moved up and down by the elevator 204.

Further, the pre-test IC stocker 201 holds the stacked customer trays holding ICs to be tested from now on. As opposed to this, the post-test IC stocker 202 holds the stacked customer trays KST on which ICs finished being tested are suitably classified.

As shown in FIG. 3, in the present embodiment, eight stockers STK-1, STK-2, . . . , STK-8 are provided as the post-test IC stockers 201. It is therefore possible to store the devices classified into as many as eight categories in accordance with the test results. That is, in addition to good and defective devices, it is possible to classify good devices into ones with operating speeds which are high, medium, and low, or defective devices into ones where retesting is required.

The above-mentioned customer tray KST is carried by an elevator table (not shown) to the loader unit 300 so as to approach the top surface through a window 151 formed in the base board 15. Further, the ICs held on the customer tray KST are reloaded to a test tray TST stopped at the position I in the loader unit 300 (see FIG. 3 to FIG. 5 and FIG. 9).

The loader unit 300 comprises an XY conveyance system 310 transferring pre-test ICs from a customer tray KST to a test tray TST. The XY conveyance system 310, as shown in FIG. 1, comprises: two rails 311 provided on the board 15; a movable arm 312 able to move back and forth between the test tray TST and the customer tray KST by the two rails 311 (this direction referred to as the “Y-direction”); and a movable head 313 supported by this movable arm 312 and able to move along the movable arm 312 in the X-axial direction.

The movable head 313 of this XY conveyance system 310 has the above-mentioned suction pad 314 (see FIG. 8) mounted on it facing downward. The XY conveyance system 310 picks up an IC from the customer tray KST with the suction pad 314, moves the IC, and releases the suction of the suction pad 314 at a predetermined position of the test tray TST so as to reload the IC from the customer tray KST to the test tray TST. Eight of these suction pads 314 are mounted on for example a single movable head 313 and can reload eight ICs at one time from a customer tray KST to a test tray TST.

Note that in the present embodiment, as shown in FIG. 1, a preciser 320 is provided between the customer tray KST and the test tray TST. The preciser 360, while not particularly shown, has relatively deep recesses. The edge of each recess is surrounded by inclined surfaces. Therefore, by dropping ICs which is reloaded from a customer tray KST to a test tray TST once into this preciser 320 before placing ICs on the test tray TST, it becomes possible to accurately set the mutual positional relationships of eight ICs and precisely reload the ICs onto the test tray TST.

When all of the holders 67 of the test tray TST hold ICs, the tray conveyance system 16 (explained later) carries the test tray TST into the chamber unit 100.

As opposed to this, when all of the ICs which had been held on a customer tray KST are reloaded on a test tray TST, the elevator lowers the empty customer tray KST. This empty tray is transferred to the tray conveyance system 205. The tray conveyance system 205 temporarily stores the empty tray in an empty tray stocker 206 once and supplies the empty tray to the stocker 202 after the customer tray KST of the post-test IC stocker 202 is filled with ICs.

The chamber unit 100 comprises: a soak chamber 110 for applying thermal stress of a high temperature or low temperature to the ICs held on the test tray TST; a test head 120 for bringing the ICs in the state given thermal stress in this soak chamber 110 into contact with a test head 5; and an unsoak chamber 130 for relieving thermal stress from the ICs tested in the test chamber 120. Note that the soak chamber 110 in the present embodiment is equivalent to one example of the application unit in the Disclosure of the Invention, the test chamber in the present embodiment is equivalent to one example of the test unit in the Disclosure of the Invention, and the unsoak chamber 130 in the present embodiment is equivalent to one example of the relieving unit in the Disclosure of the Invention.

The soak chamber 110 and the unsoak chamber 130 are arranged so as to stick out upward from the test chamber 120. As shown in FIG. 1, a base board 15 is provided between the top part of the soak chamber 110 and the top part of the unsoak chamber 130. A tray conveyance system 16 which comprises, for example, rotary rollers etc. is provided on this base board 15. This tray conveyance system 16 returns the test tray TST from the unsoak chamber 130 to the soak chamber 110 through the unloader unit 400 and the loader unit 300.

The soak chamber 110 can apply thermal stress of a high temperature or low temperature of about −55° C. to 150° C. to ICs held on a test tray TST. As shown in FIG. 9 to FIG. 13, a conveyance system 111 for horizontally moving a test tray TST supplied from a loader unit 300 by the tray conveyance system 16; a vertical conveyance system 112 for receiving a test tray TST from the horizontal conveyance system 111 and conveying it in a vertical posture in the vertical downward direction; an inversion system 113 for receiving a test tray TST from the vertical conveyance system 112, rotating the test tray TST from the vertical posture to an inverted posture, rotating it further from the inverted posture to a vertical posture, and then (that is, after rotating it by 270 degrees) transferring the test tray TST to the test chamber 120; a collection system 115 for collecting ICs dropping off from the test tray TST which is in the inverted posture; and a return system 116 for returning the IC collected by this collection system 115 to the test tray TST; are provided inside of this soak chamber 110. Note that the inversion system 113 in the present embodiment is equivalent to one example of the posture changing means in the claims.

The horizontal conveyance system 111, as shown in FIG. 10 and FIG. 11, comprises: cross-sectional L-shaped holding members 111a able to hold side parts of a test tray TST; air cylinders 111b supporting the holding members 111a which are able to move in the width direction of the test tray TST; base members 111c moving the air cylinders 111b up and down in the Z-direction; and a pair of rails 111d supporting the base members 111c which are able to move in the Y-direction.

The horizontal conveyance system 111 receives a test tray TST from the tray conveyance system 16 at one end of the rails 111d. The base members 111c raise the air cylinders 111b somewhat, then move to the other ends of the rails 111d and the air cylinders 111b drive so as to spread apart the holding members 111a and release the test tray TST, whereby the test tray TST is transferred to the clamps 112a of the vertical conveyance system 112.

The vertical conveyance system 112, as shown in FIG. 9 and FIG. 11, comprises: a plurality of clamps 112a able to hold a test tray TST in a horizontal posture; and an endless belt conveyor 112b at which these clamps 112a are provided at substantially equal intervals, and can moves the plurality of clamps 112a in the vertical direction by the belt conveyor 112b.

When a test tray TST is supplied from the horizontal conveyance system 111, the vertical conveyance system 112 lowers the test tray TST spending a certain time in the state held in a horizontal posture by the clamps 112a (position II of FIG. 3 to FIG. 5 and FIG. 9). During this time, the plurality of ICs held on the test tray TST are given high temperature or low temperature thermal stress.

The inversion system 113, as shown in FIG. 11 and FIG. 12, comprises: a rail 113a provided along the Z-axial direction so as to face the belt conveyor 112b of the vertical conveyance system 112; a movable arm 113b provided on the rail 113a, movable along the Z-axial direction and able to extend and retract in the Y-axial direction; a movable head 113c provided at the front end of this movable arm 113b and able to rotate about the X-axis; and a chuck 113d provided at the movable head 113c, able to extend and retract along the X-direction and able to grip a test tray TST.

This inversion system 113, as shown in the figure, receives a test tray TST from the clamp 112a positioned at the bottommost stage of the vertical conveyance system 112, rotates the test tray TST first from the horizontal posture to the inverted posture by 180 degrees moving the test tray TST downward, then rotates it from the inverted posture to the vertical posture by 90 degrees and transfers the test tray TST to the guide rail 101 (position III of FIG. 3 to FIG. 5 and FIG. 9). That is, the inversion system 113 rotates the test tray TST counterclockwise by 270 degrees.

The test tray TST placed on the guide rail 101 is pushed out to the test chamber 120 in the vertical posture by the belt conveyance system 102 provided in parallel to the top part of the guide rail 101. This guide rail 101 and the belt conveyance system 102 communicate with the test chamber 120 and the unsoak chamber 130 through the exit 114 of the soak chamber 110.

In the present embodiment, the posture of the test tray TST holding the ICs is inverted before the test, whereby ICs unsuitably held in the holders 67 of the test tray TST drop off from the test tray TST, so the ICs can be easily removed, and the test tray TST and ICs can be prevented from being damaged at the time of testing.

Note that it is also possible to maintain the inverted posture for a predetermined time (for example several seconds) to promote the dropping of ICs from the test tray TST. Further, when the test tray TST is in the inverted posture, the movable head 113c of the inversion system 113 may extend or retract in the X-direction or the movable arm 113b may move back and forth slightly along the Z-direction so as to vibrate the test tray TST and thereby promote the dropping of ICs from the test tray TST.

Further, in the present embodiment, the test tray TST is rotated in the soak chamber 110 and the time where the test tray TST is in the vertical posture is shortened, so it is possible to prevent ICs suitably held on the test tray TST from dropping off and possible to absord the rotating time into the thermal application time.

Furthermore, in the present embodiment, the inversion system 113 is provided at the posterior half part of the soak chamber 110 and is provided near the exit 114 from the soak chamber 110 to the test chamber 120 (see FIG. 5). Due to this, the time where the test tray TST is in the vertical posture is further shortened and the dropping of ICs can be further prevented.

Note that in the present embodiment, the “horizontal posture” means the posture where the main surface of the test tray TST faces in the vertical direction and input/output terminals of the IC face downward. The “inverted posture” means the posture where the main surface of the test tray TST faces in the vertical direction and input/output terminals of the IC face upward. The “vertical posture” means the posture where the main surface of the test tray TST faces in the horizontal direction.

The collection system 115, as shown in FIG. 10, FIG. 12, and FIG. 13, is configured from a mortar shaped member and is provided below the position where the inversion system 113 rotates the test tray TST by 270 degrees. An opening 115a is formed at the center bottom of this collection system 115. A carrier 117a of the return system 116 is arranged below this opening 115a. When an IC which had not been suitably held in a holder 67 drops from the test tray TST which is in the inverted posture by the inversion system 113, the IC falls along the inside surface of the collection system 115 toward the center and is dropped into the carrier 117a of the return system 116.

The return system 116, as shown in FIG. 13, comprises: a reciprocating movement system 117 for moving an IC collected by the collection system 115 below a first camera 118a and a movement system 119; the first camera 118a for recognizing the position and posture of the IC held on the carrier 117a of the reciprocating movement system 117; the movement system 119 for moving the IC held on the carrier 117a to the test tray TST; and a second camera 118b for detecting a holder 67 of the test tray TST in which no IC is held (from which an IC has dropped).

The reciprocating movement system 117 comprises: a carrier 117a having a recess into which an IC collected by the collection system 115 is dropped; and a rail 117b on which this carrier 117a can reciprocatingly move. When dropping an IC from the collection system 115, the carrier 117a is positioned below the opening 115a of the collection system 115. Next, when recognizing the IC's position and posture by the first camera 118a, the carrier 117a moves below the first camera 118a. Next, when transferring an IC to the movement system 119, the carrier 117a moves below the movement system 119.

The first camera 118a captures the IC held in the recess of the carrier 117a in order to recognize the position and posture of the IC held in the carrier 117a of the reciprocating movement system 117 by an image processing system (not shown).

As opposed to this, the second camera 118b captures the test tray TST from above in order to detect a holder 67 which does not hold a IC in the test tray TST gripped by the inversion system 113 by an image processing system (not shown).

The movement system 119 comprises: a movable head 119a able to move in the XYZ-directions and able to rotate by θ about the Z-axis; and a suction pad 119b provided at the front end of this movable head 119a and picking up an IC by suction. The movement system 119 picks up by suction an IC held on the carrier 117a of the reciprocating movement system 117 with the suction pad 119b, raise it along the Z-direction, then move the IC onto the holder 67 recognized by the second camera 118b, and rehouse the IC in the holder 67.

The test chamber 120 has a test head 5 arranged inside it at its center. When a test tray TST is carried to a position facing the test head 5 (position V of FIG. 3, FIG. 4, and FIG. 9), as shown in FIG. 14, the ICs are pushed against the test head 5 in the state with the test tray TST vertical, and the input/output terminals HB of the ICs are brought into electrical contact with the contact pins 51 of the test head 5. For this reason, pushers 121 for pushing the ICs toward the test head 5, are provided at positions facing the test head 5. The pushers 121 push the ICs held in the carriers 65 toward the test head 5 (push toward Y-direction in FIG. 9), the ICs are brought into electrical contact with the test head 5, and the test of the electrical characteristics of the ICs are executed.

The results of the tests are stored in a storage device of the electronic device test apparatus at an address determined by the identification number assigned to the test tray TST and the identification numbers of the ICs assigned in the test tray TST.

Note that the test head 5, as shown in FIG. 10, is for example supported rotatably about the shaft 52, so it is possible to expose the contact pins 51 of the test head 5 to the outside of the handler 1 in the upward facing posture by turning the test head 5 down to the outside. Due to this, it is possible to facilitate the work of taking out the test head 5 to the outside of the handler 1.

The unsoak chamber 130 can relieve the thermal stress from the post-test ICs held on the test tray TST. This unsoak chamber 130 uses cooling air to cool the ICs in order to return them to room temperature when applying a high temperature in the soak chamber 110. While it uses hot air or a heater to heat the ICs in order to return them to a temperature of an extent not allowing condensation when applying a low temperature in the soak chamber 110.

The posture conversion system 133, vertical conveyance system 132, and horizontal conveyance system 131 are provided inside this unsoak chamber 130. The posture conversion system 133 is similar in configuration to the inversion system 113 provided in the soak chamber 110. The vertical conveyance system 132 is similar in configuration to the vertical conveyance system 112 provided in the soak chamber 110. The horizontal conveyance system 131 is similar in configuration to the horizontal conveyance system 111 provided in the soak chamber 110. Note that the posture conversion system 133 of the present embodiment is equivalent to one example of the second posture changing means in the Disclosure of the Invention.

Further, as shown in FIG. 6, a test tray TST carried along the guide rail 101 by the belt conveyance system 102 through the entrance 134 to the unsoak chamber 130 is converted from a vertical posture to a horizontal posture by the posture conversion system 133 and transferred to the vertical conveyance system 132 (position VII in FIG. 3, FIG. 5, and FIG. 9). The vertical conveyance system 132 receives the test tray TST from the posture conversion system 133 and raises the test tray TST spending a certain time in the state held in a horizontal posture (position VIII of FIG. 3, FIG. 5, and FIG. 9). During this time, the high temperature or low temperature thermal stress is removed from the plurality of ICs held on the test tray TST. The vertical conveyance system 132 carries the test tray TST to the top, then the horizontal conveyance system 131 transfers the test tray TST to the tray conveyance system 16. The tray conveyance system 16 carrys the test tray TST to the unloader unit 400.

In the present embodiment, the test tray TST is rotated in the unsoak chamber 130, whereby the time where the test tray TST is in a vertical posture is shortened, ICs are prevented from dropping off, and the rotating time can be absorbed into the thermal relief time.

Further, in the present embodiment, a posture conversion system 133 is provided at the anterior half part of the unsoak chamber 130 and is provided near the entrance 134 to the unsoak chamber 130 from the test chamber 120. Due to this, the time where the test tray TST is in the vertical posture is further shortened and ICs can be prevented more from dropping off.

The unloader unit 400 comprises two XY conveyance systems 410. Each XY conveyance system 410 has a configuration similar to the XY conveyance system 310 provided in the loader unit 300 and comprises rails 411, a movable arm 412, a movable head 413, and a suction pad 414. This XY conveyance system 410 reloads IC from a test tray TST to the customer trays KST in accordance with the test results. The test tray TST is carried out from the unsoak chamber 130 by the tray conveyance system 16 and stops at the position IX and position X (see FIG. 3, FIG. 5, and FIG. 9). The customer tray KST is carried by the elevator table to the unloader unit 400 so as to approach the top surface through the window 152 formed in the base board 15.

When a customer tray KST is filled with post-test ICs, the elevator table lowers the full customer tray KST and the full customer tray KST is transferred to the tray movement arm 205. The tray movement arm 205 stacks the customer tray KST in the stockers STK-1, STK-2, . . . , STK-8 in accordance with the classification in the post-test IC stockers 202, then takes out an empty tray from the empty tray stocker 206 and supplies it to the window 152.

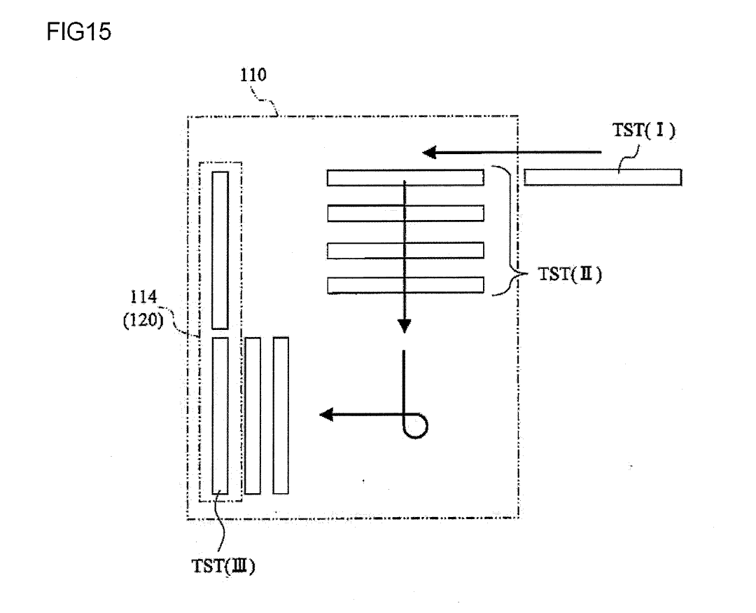

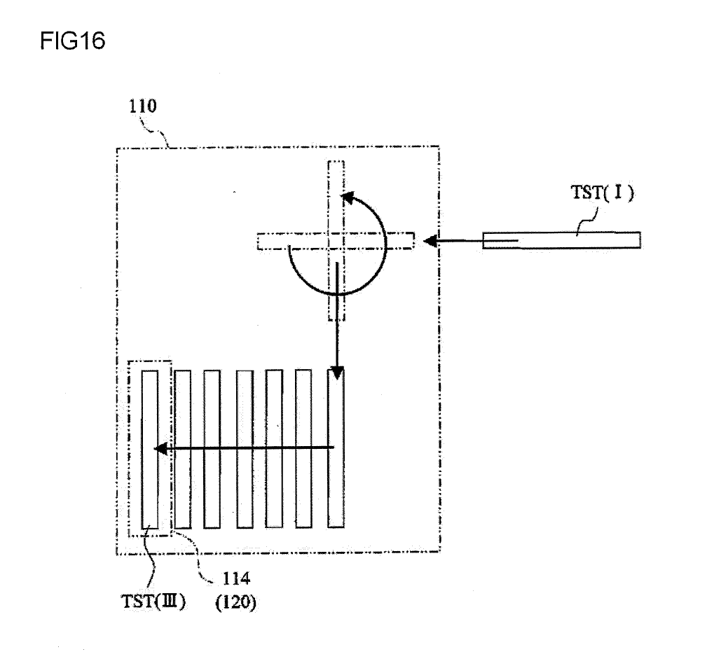

FIG. 15 is a schematic perspective view showing the handling of the test tray along the vertical direction in a soak chamber of an electronic device test apparatus according to another embodiment of the present invention, while FIG. 16 is a schematic perspective view showing the handling of the test tray along the vertical direction in a soak chamber of an electronic device test apparatus according to still another embodiment of the present invention.

As shown in FIG. 15, a buffer unit which stores several of the converted test trays TST after the inversion system 113 changes the test tray TST from a horizontal posture to a vertical posture may be provided. Further, as shown in FIG. 16, a test tray TST right after supplying from the loader unit 300 to the soak chamber 110 may be converted by the inversion system 113 from a horizontal posture to a vertical posture, and the vertical posture test tray TST successively may feed out toward the exit 114.

### Second Embodiment

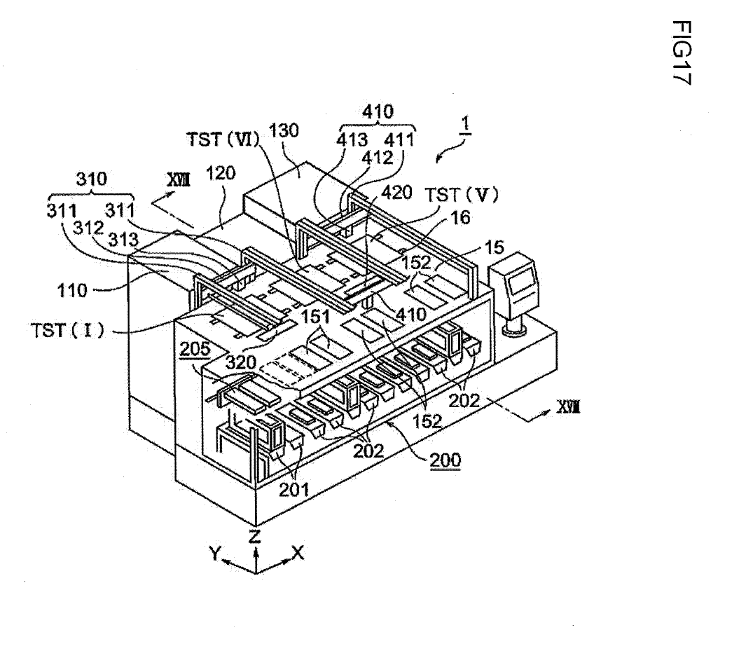

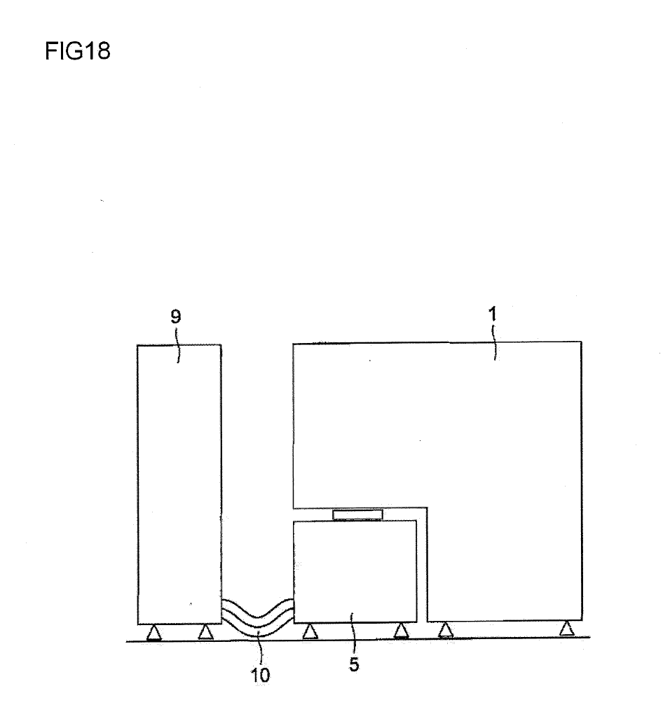

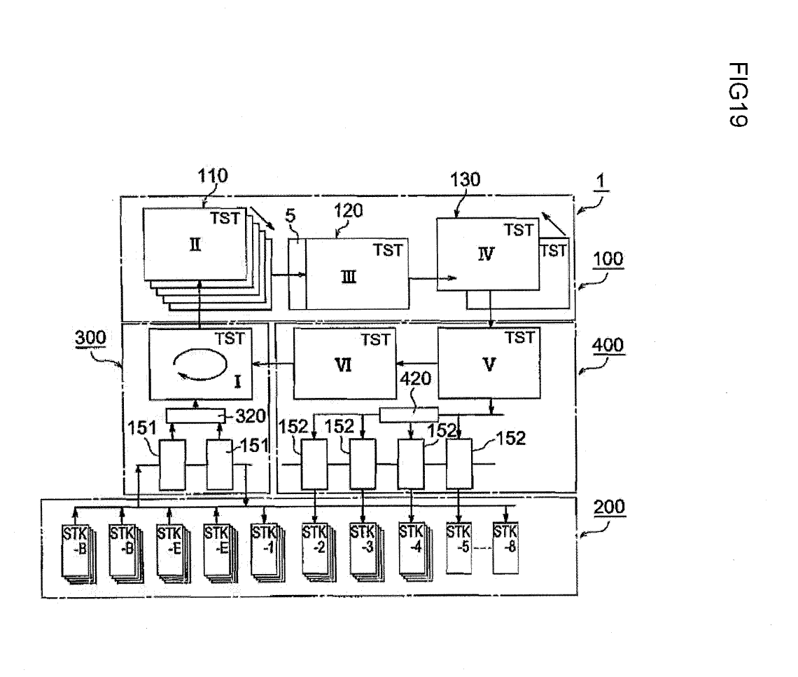

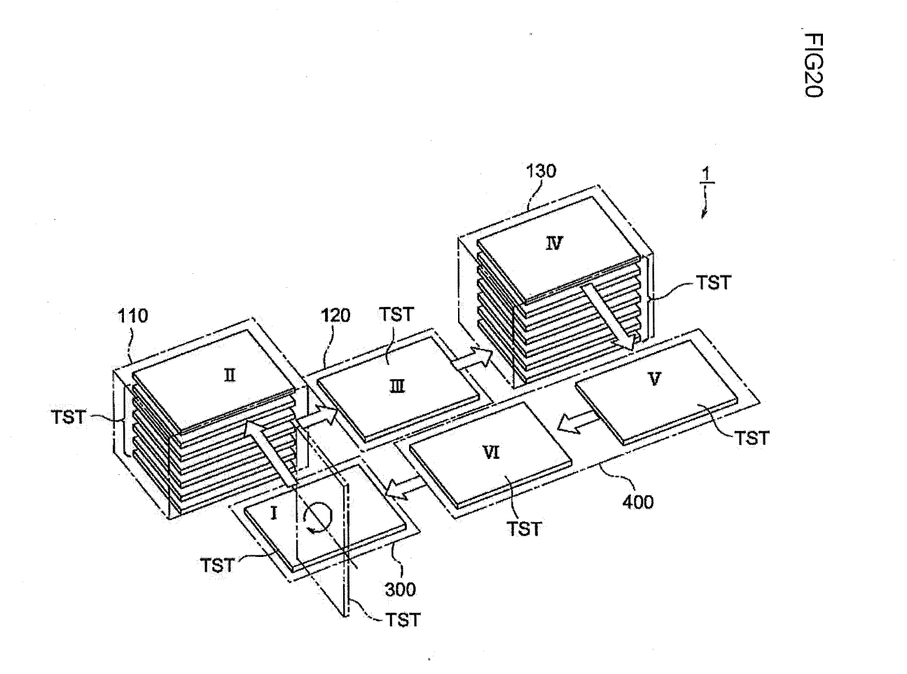

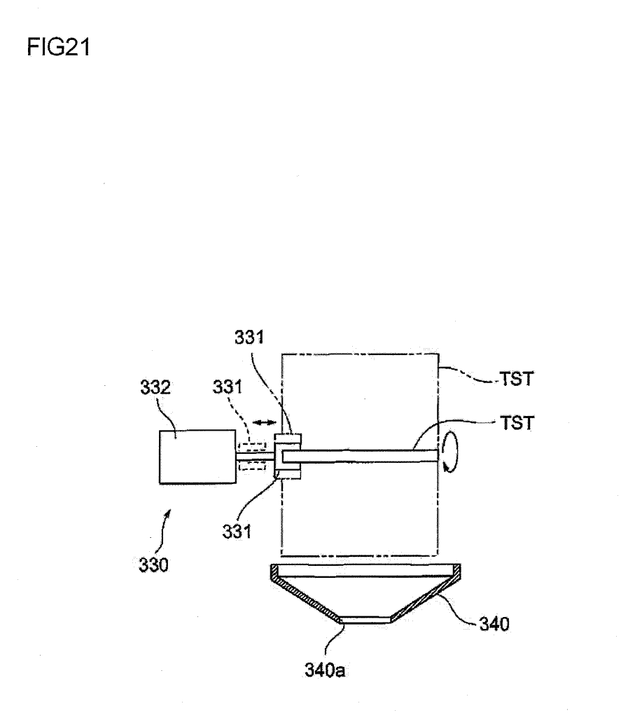

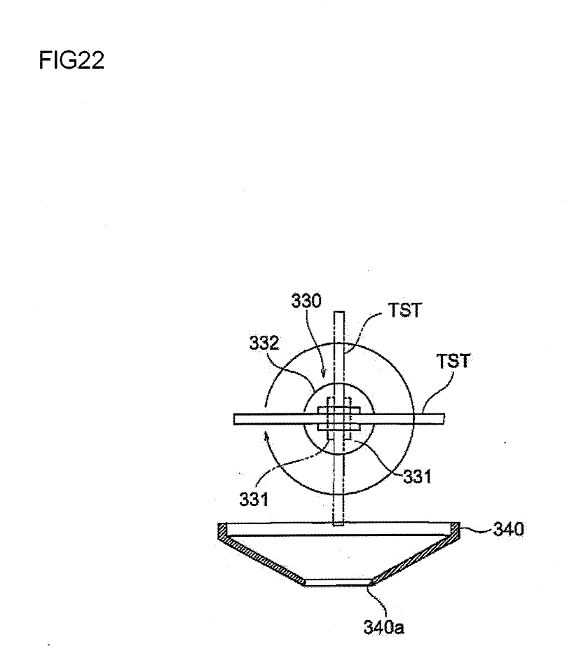

FIG. 17 is a perspective view showing an entire electronic device test apparatus according to the present embodiment, FIG. 18 is a schematic cross-sectional view along the line XVIII-XVIII of FIG. 17, FIG. 19 is a conceptual view showing the handling of a tray in an electronic device test apparatus according to the present embodiment, FIG. 20 is a schematic perspective view showing the 3D handling of a test tray in an electronic device test apparatus according to the present embodiment, and FIG. 21 and FIG. 22 are a front view and side view showing an inversion system and a collection system of an electronic device test apparatus according to the present embodiment.

The electronic device test apparatus according to the present embodiment, as shown in FIG. 17 to FIG. 19, comprises a handler 1, test head 5, and tester 9. Its basic configuration is the same as that of the electronic device test apparatus according to the first embodiment.

However, the electronic device test apparatus according to the present embodiment, as shown in FIG. 18, differs from the electronic device test apparatus according to the first embodiment in the points that the test head 5 is provided inside a recess formed in the handler 1 in the upward facing posture and that, as shown at the position III of FIG. 19 and FIG. 20, the ICs are pushed against the test head with the test tray TST in the horizontal posture in the chamber unit 100. That is, in the present embodiment, no inversion system 113 for rotating the test tray TST from the horizontal posture to the vertical posture is provided inside the soak chamber 110. Further, no posture conversion system 133 for returning the test tray TST from the vertical posture to the horizontal posture is provided inside the unsoak chamber 130 as well.

In the present embodiment, the test tray TST is inverted at the position I of the loader unit 300 shown in FIG. 19 and FIG. 20 so as to drop the ICs unsuitably held in the holders 67 of the test tray TST and prevent the test tray TST and the ICs from being broken at the time of a test.

The loader unit 300 in the present embodiment comprises an inversion system 330 which rotates the test tray TST conveyed by the tray conveyance system 16 from a horizontal posture to an inverted posture and further rotates it from the inverted posture to the horizontal posture at the position I shown in FIG. 19 and FIG. 20 (that is, rotates it by 360 degrees).

This inversion system 330, as shown in FIG. 21 and FIG. 22, comprises: chucks 331 for gripping the sides of the test tray TST; and an actuator 332 for moving or retracting the chucks 331 toward or from the test tray TST and supporting it in a rotatable manner. The actuator 332 is fixed to an apparatus board 15.

The collection system 340, like the collection system 115 in the first embodiment, is configured from a mortar shaped member and is provided below the position where the inversion system 330 rotates the test tray TST. An opening 340a is formed at the bottom of the center of this collection system 340. A ruturn system similar to the ruturn system 116 explained in the first embodiment is provided below this opening 340. Note that FIG. 21 and FIG. 22 do not particularly illustrate the ruturn system.

Further, for example, if the inversion system 330 rotates the test tray TST in the state where part of the tray conveyance system 18 is retracted, ICs unsuitably held in the holders 67 drop off from the test tray TST, and the ICs are collected by the collection system 330 and are held again on the test tray by the ruturn system. The test tray with unsuitably held ICs again held is carried by the tray conveyance system 18 into the soak chamber 110.

In the present embodiment, the test tray TST holding the ICs is inverted in the inverted posture before testing, so ICs not held in the holders 67 of the test tray TST drop off from the test tray TST, so the ICs can be easily removed and the test tray TST and ICs can be prevented from being damaged at the time of testing.

Note that it is also possible to maintain the inverted posture for a predetermined time (for example several seconds) and promote the dropping of ICs from the test tray TST. Further, when the test tray TST is in the inverted posture, it is also possible to extend and retract the actuator 332 of the inversion system 330 to apply vibration to the test tray TST and thereby promote the dropping of ICs from the test tray TST.

Note that in the same way as the first embodiment, in the present embodiment as well, the “horizontal posture” means the posture where the main surface of the test tray TST faces in the vertical direction and input/output terminals of the IC face downward. The “inverted posture” means the posture where the main surface of the test tray TST faces in the vertical direction and input/output terminals of the IC face upward. The “vertical posture” means the posture where the main surface of the test tray TST faces in the horizontal direction.

Note that the embodiments explained above were described to facilitate understanding of the present invention and were not described for limiting the present invention. Therefore, the elements disclosed in the above embodiments include all design changes and equivalents falling within the technical scope of the present invention.

1. An electronic device test apparatus used for bringing devices under test into electrical contact with contact parts of the test head in the state where the devices under test are held on a test tray, and running tests on the electrical characteristics of the devices under test,
the electronic device test apparatus comprising:
a posture changer configured to change a posture of the test tray which holds the devices under test in a direction dropping devices under test which are insufficiently held at least once before testing.

2. The electronic device test apparatus as set forth in claim 1, wherein the posture changer changes the test tray from a horizontal posture to an inverted posture and furthermore changes the test tray from the inverted posture to a predetermined posture.

3. The electronic device test apparatus as set forth in claim 2, wherein the posture changer changes the test tray from a horizontal posture to an inverted posture, maintains the inverted posture for a predetermined time, then changes the test tray from the inverted posture to a predetermined posture.

4. The electronic device test apparatus as set forth in claim 2, wherein the posture changer changes the test tray from a horizontal posture to an inverted posture, vibrates the test tray in the inverted posture, then changes the test tray from the inverted posture to a predetermined posture.

5. The electronic device test apparatus as set forth in claim 2, further comprising: a collector configured to collect the device under test dropped from the test tray which is in an inverted posture by the posture changer.

6. The electronic device test apparatus as set forth in claim 5, comprising: a returning device configured to return the device under test collected by the collector to the test tray, another test tray, or a customer tray.

7. A method of testing electronic devices bringing devices under test into electrical contact with contact parts of the test head in the state where the devices under test are held on a test tray, and running tests on the electrical characteristics of the devices under test,
the method of testing electronic devices comprising:
changing a posture of the test tray which holds the devices under test in a direction dropping devices under test which are insufficiently held at least once before testing.

8. The method of testing electronic devices as set forth in claim 7, wherein the test tray is changed from a horizontal posture to an inverted posture and is furthermore changed from the inverted posture to the predetermined posture.

9. The method of testing electronic devices as set forth in claim 8, wherein the test tray is changed from a horizontal posture to an inverted posture, is maintained in the inverted posture for a predetermined time, then is changed from the inverted posture to the predetermined posture.

10. The method of testing electronic devices as set forth in claim 8, wherein the test tray is changed from a horizontal posture to an inverted posture, is vibrated in the inverted posture, then is changed from the inverted posture to the predetermined posture.

11. The method of testing electronic devices as set forth in claim 8, further comprising: collecting a device under test dropped from the test tray which is in an inverted posture.

12. A method of testing electronic devices as set forth in claim 11, further comprising: returning the device under test collected to the test tray, another test tray, or a customer tray.
